(19) United States
(12) Patent Application Publication
(10) Pub. No.: US 2022/0162750 A1
(43) Pub. Date: May 26, 2022

(54) POWDER ATOMIC LAYER DEPOSITION APPARATUS WITH SPECIAL COVER LID

(71) Applicant: SKY TECH INC., Hsinchu County (TW)

(72) Inventors: JING-CHENG LIN, Hsinchu County (TW); JUNG-HUA CHANG, Hsinchu County (TW); CHIA-CHENG KU, Hsinchu County (TW)

(21) Appl. No.: 17/334,774

(22) Filed: May 30, 2021

(30) Foreign Application Priority Data
Nov. 24, 2020 (TW) 109141125

(51) Int. Cl. C23C 16/455; C23C 16/52; C23C 16/56; C23C 16/44

(52) U.S. Cl. CPC C23C 16/45544; C23C 16/4417; C23C 16/56; C23C 16/52

(57) ABSTRACT

A powder atomic layer deposition apparatus with special cover lid is disclosed, which includes a vacuum chamber, a shaft sealing device, and a driving unit that drives the vacuum chamber to rotate through the shaft sealing device. The vacuum chamber includes a chamber and a cover lid having an inner surface. At least one fan unit and a monitor wafer are arranged on the inner surface of the cover lid, wherein the monitor wafer is located between the fan unit and the cover lid, and there is a gap between the monitor wafer and the fan unit. An air intake line directs a gas toward the fan unit, and the fan unit drives the gas to flow throughout a reaction space, so that powders in the reaction space are blown around for thin films of uniform thickness to form on the surface of the powders and the monitor wafer.

### REFERENCE TO RELATED APPLICATIONS

This non-provisional application claims priority claim under 35 U.S.C. § 119(a) on Taiwan Patent Application No. 109141125 filed Nov. 24, 2020, the entire contents of which are incorporated herein by reference.

### TECHNICAL FIELD

The present disclosure relates to a powder atomic layer deposition apparatus with special cover lid, more particularly, to a powder atomic layer deposition apparatus that has a fan unit disposed on a cover lid of a vacuum chamber for driving gas to blow powders in a reaction space, so as to facilitate a formation of thin films with uniform thickness on the surface of the powders and a monitor wafer.

### BACKGROUND

Nanoparticle is generally defined as a particle that is smaller than 100 nanometers in at least one dimension, and in comparison to macroscopic matter, nanoparticle is completely different in both physical and chemical properties. Broadly speaking, the physical property of macroscopic matter is unrelated to its size, but the same cannot be said for nanoparticle. Nanoparticles are currently being studied for potential applications in biomedical, optical, and electronic fields.

Quantum dot is a semiconductor nanoparticle and the semiconductor material currently being studied includes materials in groups II-VI like ZnS, CdS, CdSe, etc, in which CdSe is the most promising. The size of Quantum dot is usually between 2 to 50 nanometers. Electron in the quantum dot absorbs energy after being irradiated by ultra-violet light and transitions from valence band to conductance band. When the stimulated electron returns to the valence band from the conductance band, it releases the energy by emission of light.

The energy gap of a quantum dot is associated to its size, wherein the larger the size of a quantum dot, the smaller the energy gap which in turn emits light with longer wavelength after radiation, and the smaller the size of a quantum dot, the larger the energy gap which in turn emits light with shorter wavelength after radiation. For example, a quantum dot of 5 to 6 nanometers emits orange or red light, whereas a quantum dot of 2 to 3 nanometers emits blue or green light; the light color is, of course, determined by the material composition of the quantum dot.

Light generated by light emitting diode (LED) that utilizes quantum dots is near continuous spectrum and has good color rendering, which are beneficial in improving the luminous quality of LED. In addition, the wavelength of the emitted light can be adjusted by changing the size of quantum dot. Therefore quantum dots have become a main focus in developing the next generation of light-emitting devices and displays.

Although nanoparticles and quantum dots have the aforementioned advantages and properties, agglomeration of the nanoparticles occurs easily during manufacturing process. Moreover, nanoparticles have higher surface activities and are prone to react with air and water vapor, which are factors that shorten the life cycle of nanoparticles.

In particular, agglomeration occurs when the quantum dots are being manufactured as sealant for LED and thereby decreasing the optical performance of quantum dots. Further, after the quantum dots are made as the sealant of LED, it is still possible for surrounding oxygen or water vapor to penetrate through the sealant and come in contact with the surface of the quantum dots, thereby causing the quantum dots to be oxidized and affecting the efficacy or life cycle of the quantum dots and LED. The surface defects and dangling bonds of the quantum dots may also cause non-radiative recombination, which also affects the luminous efficiency of quantum dots.

Atomic layer deposition (ALD) is a process currently used by industries to form a thin film with nanometer thickness or a plurality of thin films on the surface of the quantum dots to form a quantum well.

ALD process can form a thin film with a uniform thickness on a substrate with precision in controlling the thickness of the thin film, and so in theory ALD process could also be applicable to three-dimensional quantum dots. When the quantum dots sit on a support pedestal, contacts exist between adjacent quantum dots, and these contacts cannot be reached by a precursor gas of ALD. Thus, thin films with uniform thickness cannot be formed on the surface of all nanoparticles.

### SUMMARY

To solve the aforementioned issues, an object of the present disclosure is to provide a powder atomic layer deposition apparatus which has a specially designed cover lid, wherein a fan unit is disposed on an inner surface of the cover lid of a vacuum chamber. Gas being delivered to the reaction space flows toward the fan unit and the fan unit drives the gas to flow to various areas in the reaction space. Thus, powders in the reaction space are fully agitated, which is beneficial in forming a thin film with a uniform thickness on the surface of each powder by ALD process.

An object of the present disclosure is to provide a powder atomic layer deposition apparatus with special cover lid, mainly including a driving unit, a shaft sealing device, and a vacuum chamber. The driving unit is connected to the vacuum chamber via the shaft sealing device and drives the vacuum chamber to rotate through the shaft sealing device. The vacuum chamber includes a cover lid and a chamber, wherein an inner surface of the cover lid covers the chamber and a reaction space is formed between the cover lid and the chamber. The reaction space is used to accommodate a plurality of powders. A fan unit is disposed on the inner surface of the cover lid, and through the shaft sealing device, the driving unit drives the vacuum chamber and the fan unit to rotate relative to an air intake line. When the air intake line directs a gas to flow toward the fan unit, the rotating fan unit drives the gas to circulate in the reaction space to blow the powders around in the reaction space. Through the rotating vacuum chamber and the fan unit driving the gas to blow the powders around, the powders in the reaction space are completely and evenly stirred and agitated.

The air intake line can also deliver a precursor gas to the reaction space, wherein the rotating unit would drive the precursor gas to flow throughout all regions of the reaction space and to come in contact with the powders in the reaction space, so as to form thin films with uniform thickness on the surface of the powders.

An object of the present disclosure is to provide a powder atomic layer deposition apparatus with special cover lid, in which a fan unit and a monitor wafer are disposed on an inner surface of the cover lid of a vacuum chamber, and there is a gap between the fan unit and the inner surface of the cover lid and/or the monitor wafer. When performing ALD process to powders in the reaction space of the vacuum chamber, a precursor gas passes through the gap between the fan unit and the cover lid and comes in contact with the monitor wafer to form a thin film on the surface of the monitor wafer. In practice, a thickness of the thin film on the surface of the monitor wafer can be measured to infer a thickness of a thin film formed on the surface of the powders.

An object of the present disclosure is to provide a powder atomic layer deposition apparatus with special cover lid, wherein a vacuum chamber includes a cover lid and a chamber. A recess is disposed at an inner surface of the cover lid, and a corresponding space is disposed in the chamber. A fan unit and a monitor wafer are disposed in the recess of the cover lid. The recess of the cover lid and the space of the chamber form a reaction space, and the fan unit and the monitor wafer are located in the reaction space.

To achieve the aforementioned objects, the present disclosure provides a powder atomic layer deposition apparatus with special cover lid, which includes a vacuum chamber, at least one fan unit, a shaft sealing device, a driving unit, at least one air extraction line, and at least one air intake line. The vacuum chamber includes a cover lid and a chamber, and an inner surface of the cover lid covers the chamber to form a reaction space between the cover lid and the chamber. The fan unit is disposed on the inner surface of the cover lid, and the shaft sealing device is connected to the vacuum chamber. The driving unit is connected to the shaft sealing device and drives the vacuum chamber to rotate through the shaft sealing device. The air extraction line is fluidly connected to the reaction space of the vacuum chamber for extracting a gas in the reaction space. The air intake line is fluidly connected to the reaction space of the vacuum chamber for transporting a precursor gas or a gas to the reaction space, wherein the gas flows toward the fan unit on the inner surface of the cover lid and is driven by the fan unit to blow powders around in the reaction space.

Preferably, the powder atomic layer deposition apparatus with special cover lid includes a monitor wafer disposed on the inner surface of the cover lid between the fan unit and the cover lid.

Preferably, the powder atomic layer deposition apparatus with special cover lid includes a plurality of securing portions disposed on and protruding from the inner surface of the cover lid, and the fan unit is disposed on the securing portions to form a gap between the fan unit and the cover lid.

Preferably, the cover lid has a recess disposed on the inner surface of the cover lid, and the monitor wafer and the fan unit are disposed in the recess.

Preferably, the recess in the cover lid is a wavy circular recess, and the chamber has a space which is a wavy circular recess, wherein the reaction spaced formed by the cover lid and the chamber has a wavy circular columnar shape.

Preferably, the air intake line includes at least one gas line fluidly connected to the reaction space of the vacuum chamber for transporting the gas toward the fan unit on the inner surface of the cover lid, and the fan unit drives the gas to blow the powders around in the reaction space.

Preferably, the shaft sealing device includes an outer tube and an inner tube. The outer tube has an accommodating space for accommodating the inner tube, and the inner tube has a connection space for accommodating the air extraction line, the air intake line, and the gas line.

Preferably, the powder atomic layer deposition apparatus further includes a heater and a temperature sensing unit disposed in the inner tube. The heater is used to heat the connection space of the inner tube, and the temperature sensing unit is used to measure a temperature of the connection space of the inner tube.

Preferably, the inner tube extends from the accommodating space of the outer tube to the reaction space of the vacuum chamber and forms a protruding tube part in the reaction space. The gas line is disposed in the inner tube and the protruding tube part for transporting the gas to the fan unit.

Preferably, the fan unit includes a mount rack and a plurality of blades. The blades are disposed on the base plate and protrude in a direction toward the chamber.

### BRIEF DESCRIPTION OF THE DRAWINGS

The structure as well as preferred modes of use, further objects, and advantages of this present disclosure will be best understood by referring to the following detailed description of some illustrative embodiments in conjunction with the accompanying drawings, in which:

FIG. 1 is a schematic diagram of a powder atomic layer deposition apparatus with special cover lid according to an embodiment of the present disclosure;

FIG. 2 is a cross-sectional schematic diagram of a powder atomic layer deposition apparatus with special cover lid according to an embodiment of the present disclosure;

FIG. 3 is a cross-sectional schematic diagram illustrating a shaft sealing device of a powder atomic layer deposition apparatus with special cover lid according to an embodiment of the present disclosure;

FIG. 4 is a schematic diagram illustrating a vacuum chamber of a powder atomic layer deposition apparatus with special cover lid according to an embodiment of the present disclosure;

FIG. 5 is an exploded schematic diagram illustrating a vacuum chamber of a powder atomic layer deposition apparatus with special cover lid according to an embodiment of the present disclosure;

FIG. 6 is an exploded schematic diagram illustrating a vacuum chamber of a powder atomic layer deposition apparatus with special cover lid according to another embodiment of the present disclosure;

FIG. 7 is a schematic diagram illustrating a vacuum chamber of a powder atomic layer deposition apparatus with special cover lid according to another embodiment of the present disclosure;

FIG. 8 is a cross-sectional schematic diagram of a powder atomic layer deposition apparatus with special cover lid according to another embodiment of the present disclosure; and

FIG. 9 is a cross-sectional exploded diagram of a powder atomic layer deposition apparatus with special cover lid according to another embodiment of the present disclosure.

### DETAILED DESCRIPTION OF THE PREFERRED EMBODIMENTS

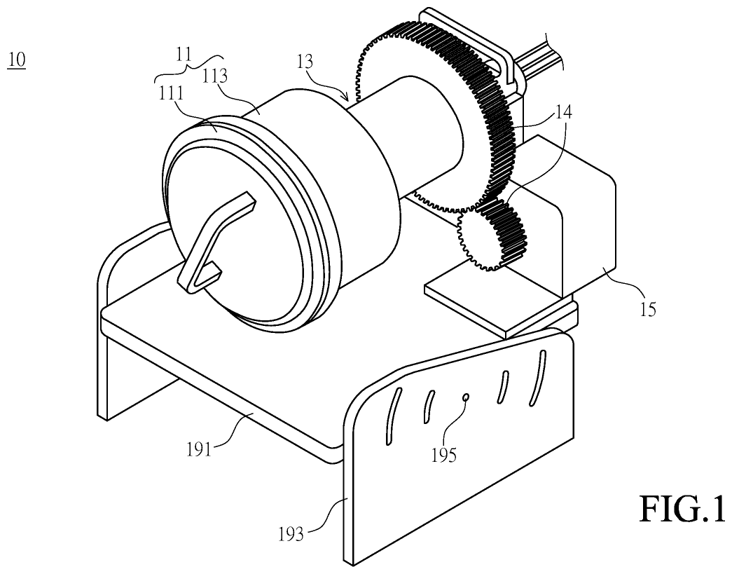

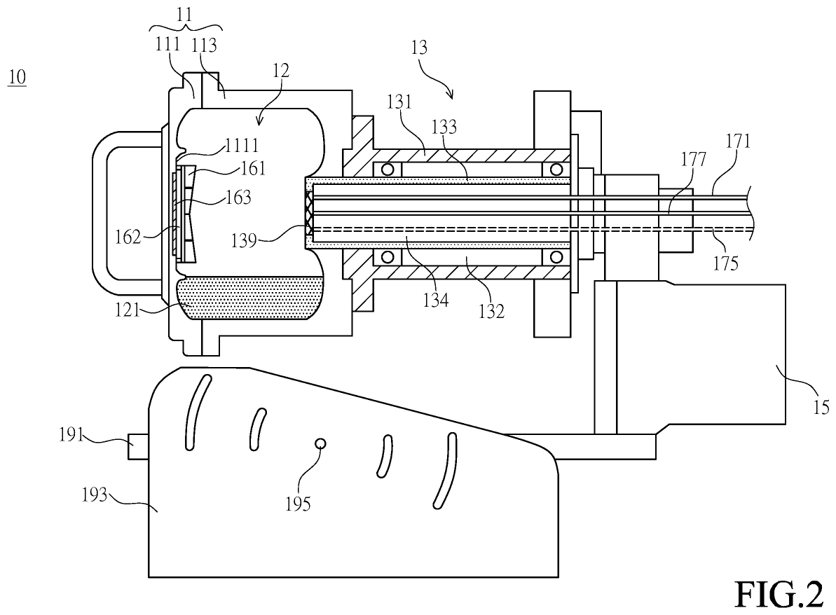

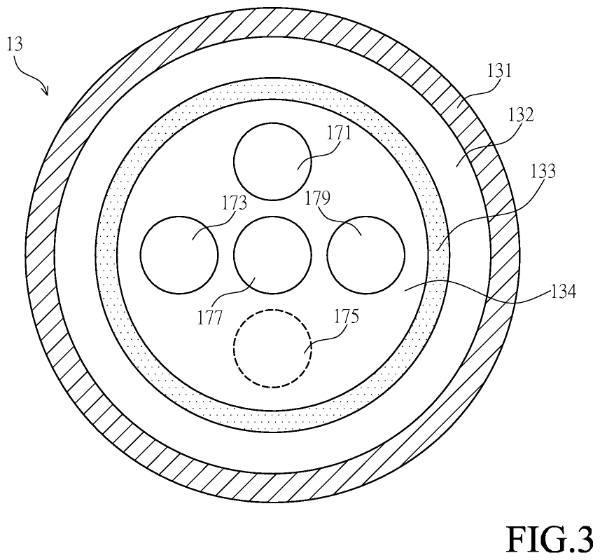

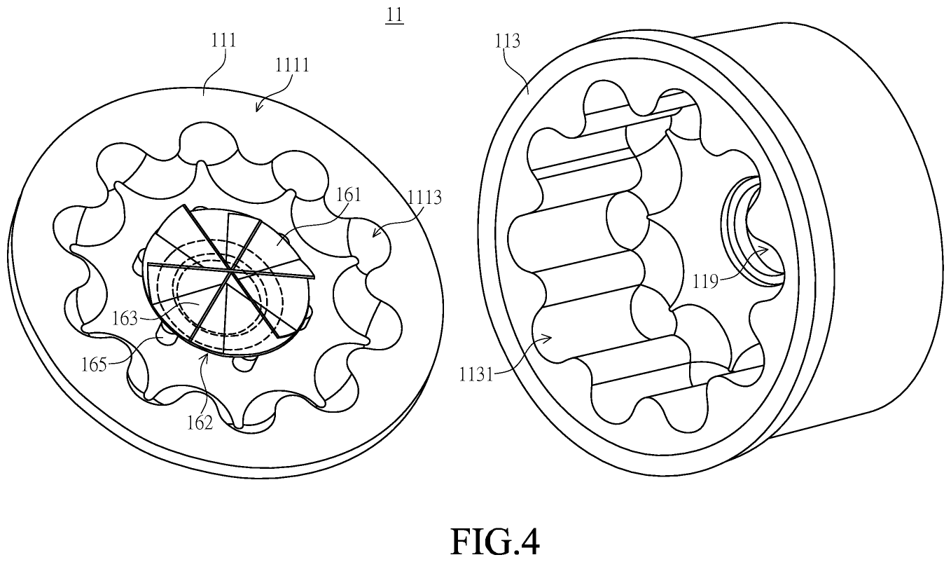

Referring to FIG. 1, FIG. 2, FIG. 3 and FIG. 4, a powder atomic layer deposition apparatus with special cover lid 10 includes a vacuum chamber 11, a shaft sealing device 13, and a driving unit 15. As shown in the figures, the driving unit 15 is connected to the vacuum chamber 11 via the shaft sealing device 13 and drives the vacuum chamber 11 to rotate.

The vacuum chamber 11 has a reaction space 12 for accommodating a plurality of powders 121 such as quantum dots. The quantum dots may be made of semiconductor material like ZnS, CdS, CdSe, etc in groups II-VI, and a thin film formed on each of the quantum dots may be aluminum oxide (Al₂O₃). The aforementioned materials are merely examples of the present disclosure and the claim scope of the present disclosure is not limited thereby.

At least one air extraction line 171, at least one air intake line 173 and/or at least one gas line 175 are fluidly connected to the reaction space 12 of the vacuum chamber 11. For Example, the air extraction line 171, the air intake line 173, the gas line 175, a heater 177 and/or a temperature sensing unit 179 may be disposed in the shaft sealing device 13 as shown in FIG. 3. The air extraction line 171 is fluidly connected to the reaction space 12 of the vacuum chamber 11 and is used to extract gas from the reaction space 12 to create vacuum in the reaction space 12 for subsequent ALD process. In particular, the air extraction line 171 can connect to a pump and use the pump to extract the gas in the reaction space 12.

The air intake line 173 is fluidly connected to the reaction space 12 of the vacuum chamber 11 and is used to transport a precursor gas or a gas to the reaction space 12, wherein the gas may be a non-reactive gas. The air intake line 173 can, for example, be connected to a precursor gas storage tank and a non-reactive gas storage tank via a valve set, and through the valve set, transport the precursor gas to the reaction space 12 for the precursor gas to be deposited on the surface of each powder 121. In practical application, the air intake line 173 may transport a carrier gas together with the precursor gas to the reaction space 12. Then, the air intake line 173 transports the non-reactive gas to the reaction space 12 through the valve set in addition to the air extraction line 171 extracting gas from the reaction space 12, to remove unreacted precursor gas in the reaction space 12. In one embodiment, the air intake line 173 is connected to a plurality of branch lines and transports different precursor gases to the reaction space 12 sequentially through the respective branch lines.

The air intake line 173 is also capable of increasing a flow of gas delivered to the reaction space 12, so as to blow the powders 121 around in the reaction space 12 by the gas, such that the powders 121 are carried by the gas and diffused to various areas and all regions of the reaction space 12.

In one embodiment, the air intake line 173 includes at least one gas line 175, wherein the gas line 175 is fluidly connected to the reaction space 12 of the vacuum chamber 11 and is used to transport a non-reactive gas or a gas to the reaction space 12. The gas line 175 can, for example, be connected to a nitrogen storage tank via a valve set, and through the valve set, transport nitrogen to the reaction space 12. The gas is used to blow the powders 121 around in the reaction space 12, and in combination with the rotating of the vacuum chamber 11 driven by the driving unit 15, the powders 121 in the reaction space 12 are effectively and evenly stirred and agitated, thereby contributing in forming a thin film with a uniform thickness on the surface of each powder 121.

The air intake line 173 and the gas line 175 of the powder atomic layer deposition apparatus with special cover lid 10 are both used to transport gas to the reaction space 12. The flow of gas transported by the air intake line 173 is smaller as the main purpose of which is for removing the precursor gas in the reaction space 12, whereas the flow of gas transported by the gas line 175 is larger and is mainly used to blow the powders 121 around in the reaction space 12. The gas transported by the air intake line 173 and by the gas line 175 may be the same gas or may be different gases.

The timings at which the air intake line 173 and the gas line 175 transport the gas to the reaction space 12 are different. Hence, the gas line 175 may be omitted in practical application, and instead, the flow of gas transported by the air intake line 173 at different timings is adjusted. More specifically, when removing the precursor gas from the reaction space 12, the flow of gas being transported to the reaction space 12 by the air intake line 173 is lowered, and when blowing the powders 121 around in the reaction space 12, the flow of gas being transported to the reaction space 12 by the air intake line 173 is enlarged.

In one embodiment, the shaft sealing device 13 includes an outer tube 131 and an inner tube 133, wherein the outer tube 131 has an accommodating space 132 and the inner tube 133 has a connection space 134. The outer tube 131 and the inner tube 133 may, for example, be hollow columnar objects. The accommodating space 132 of the outer tube 131 is used to accommodate the inner tube 133, and the outer tube 131 and the inner tube 133 are configured to be coaxial.

The shaft sealing device 13 can be a common shaft seal or a magnetic fluid shaft seal that is mainly used for isolating the reaction space 12 of the vacuum chamber 11 from outer spaces to maintain vacuum in the reaction space 12.

In one embodiment of the present disclosure, a filter unit 139 is disposed at one end of the inner tube 133 that is connected to the reaction space 12. The air extraction line 171 is fluidly connected to the reaction space 12 via the filter unit 139, and extracts the gas from the reaction space 12 to pass through the filter unit 139. The filter unit 139 is mainly used to filter the powders 121 in the reaction space 12 to prevent the powders 121 from entering the air extraction line 171 during gas extraction and causing a loss of the powders 121.

The driving unit 15 is mechanically connected to the vacuum chamber 11 via the outer tube 131, and drives the vacuum chamber 11 to rotate through the outer tube 131. The driving unit 15 is not connected to the inner tube 133, therefore when the driving unit 15 drives the outer tube 131 and the vacuum chamber 11 to rotate, the inner tube 133 does not rotate along therewith, which in turn keeps a stable extraction or supply of gas by the air extraction line 171, the air intake line 173 and/or the gas line 175 in the inner tube 133.

The driving unit 15 may drive the outer tube 131 and the vacuum chamber 11 to rotate continuously in one direction or the same direction, like clockwise or counterclockwise. In different embodiments, the driving unit 15 may drive the outer tube 131 and the vacuum chamber 11 to rotate in the clockwise direction by a specific angle, and then in the counterclockwise direction by the specific angle; the angle is, for example, 360 degrees. As the vacuum chamber 11 rotates, the powders 121 in the reaction space 12 are stirred and agitated, which in turn facilitates the powders 121 to come in contact with a precursor gas.

In one embodiment, the driving unit 15 is a motor, which is connected to the outer tube 131 via a gear 14. As shown in FIG. 2 and FIG. 3, the air extraction line 171, the air intake line 173, the gas line 175, the heater 177 and/or the temperature sensing unit 179 are disposed in the connection space 134 of the inner tube 133.

The heater 177 is used to heat the connection space 134 and the inner tube 133. By heating the air extraction line 171, the air intake line 173 and/or the gas line 175 in the inner tube 133 with the heater 177, temperatures of the gases in the air extraction line 171, the air intake line 173 and/or the gas line 175 are raised. For example, the temperature of gas and/or precursor gas transported by the air intake line 173 to the reaction space 12 may be raised, and the temperature of gas transported by the gas line 175 to the reaction space 12 may be raised. As such, when the gas and/or the precursor gas enter the reaction space 12, the temperature of the reaction space 12 would not drop or change drastically. Moreover, the temperature sensing unit 179 is used to measure the temperature of the heater 177 or the connection space 134 to monitor an operation status of the heater 177. Additional heating device is also often disposed inside of, outside of, or surrounding the vacuum chamber 11, wherein the heating device is adjacent to or in contact with the vacuum chamber 11 for heating the vacuum chamber 11 and the reaction space 12.

In some embodiments like that shown in FIG. 2 and FIG. 4, the vacuum chamber 11 includes a cover lid 111 and a chamber 113, wherein an inner surface 1111 of the cover lid 111 is used to cover the chamber 113 so as to form the reaction space 12 between the cover lid 111 and the chamber 113.

At least one fan unit 161 is disposed on the inner surface 1111 of the cover lid 111. The gas and/or the precursor gas transported by the air intake line 173 and/or the gas line 175 to the reaction space 12 flows toward the fan unit 161, and the fan unit 161 guides or drives the gas and/or the precursor gas to spread throughout all regions of the reaction space 12 so as to blow the powders 121 around in the reaction space 12.

More particularly, when the air intake line 173 and/or the gas line 175 transports the gas and/or the precursor gas to the reaction space 12, the driving unit 15 drives the vacuum chamber 11 and the fan unit 161 to rotate relative to the air intake line 173 and/or the gas line 175. The rotating fan unit 161 acts like a fan which drives gas to circulate in the reaction space 12 and to blow the powders 121 in the reactions space 12 around. Furthermore, the fan unit 161 can be used to drive the precursor gas transported to the reaction space 12 by the air intake line 173 to spread throughout the reaction space 12 and come in contact with the powders 121 in the reaction space.

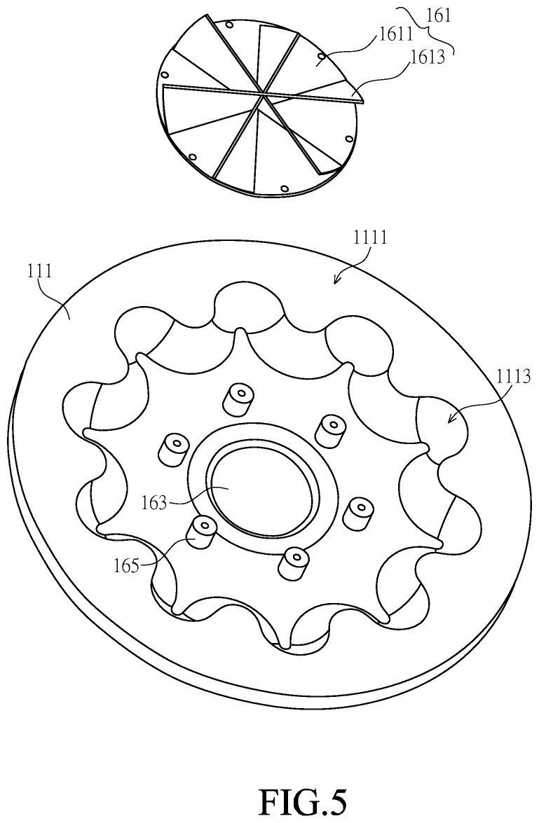

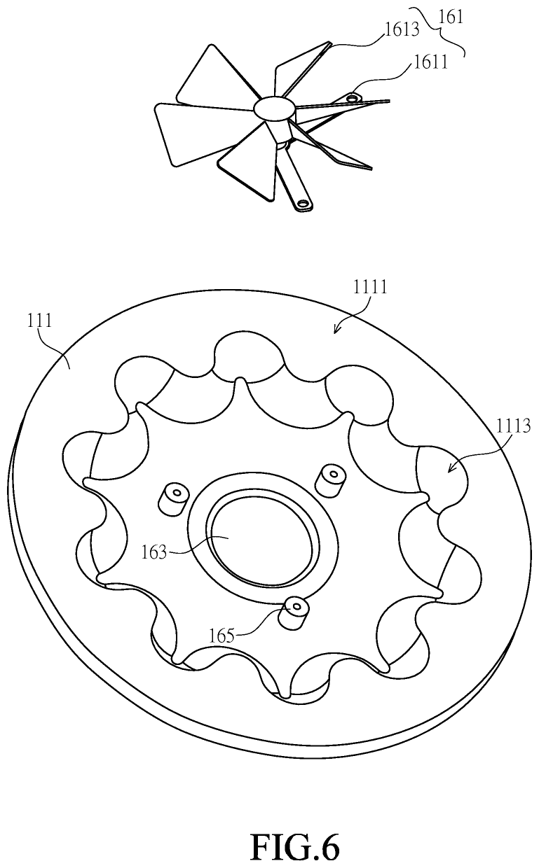

In one embodiment as shown in FIG. 5 and FIG. 6, the fan unit 161 includes a mount rack 1611 and a plurality of blades 1613. In specific, the mount rack 1611 may be a flat plate or a bracket, and the blades 1613 are disposed on the mount rack 1611 and protrude in a direction toward the chamber 113.

As shown in FIG. 5, the mount rack 1611 is a circular flat plate, and the blades 1613 are disposed on a surface of the mount rack 1611, wherein the mount rack 1611 and the blades 1613 can be integrally formed or separate components. As shown in FIG. 6, the mount rack 1611 is a bracket, and the blades 1613 are disposed on the mount rack 1611. For example, the mount rack 1611 includes three connecting brackets, and the blades 1613 are connected to the mount rack 1611 via a connecting shaft. The number of connecting brackets and the angles between adjacent connecting brackets are not limitations to the claim scope of the present disclosure. In practical application, an inclination angle between the blades 1613 and the mount rack 1611 is adjusted based on factors like air flow, size of the vacuum chamber 11, and size of the fan unit 161.

In one embodiment, the fan unit 161 is not attached to the inner surface 1111 of the cover lid 111, and there is a gap 162 between the fan unit 161 and the inner surface 1111 of the cover lid 111. A plurality of securing portions 165 may, for example, be disposed on the inner surface 1111 of the cover lid 111, wherein the securing portions 165 protrude from the inner surface 1111 of the cover lid 111. The fan unit 161 is disposed on the securing portions 165, and thus the gap 162 is formed between the fan unit 161 and the cover lid 111. Each of the securing portions 165 may have a tapped hole disposed thereon, and the fan unit 161 may have corresponding through holes disposed thereon, whereby the fan unit 165 can be fixed on the securing portions 165 through screws.

In addition, a monitor wafer 163 may be disposed on the inner surface 1111 of the cover lid 111 and located between the inner surface 1111 of the cover lid 111 and the fan unit 161, wherein the monitor wafer 163 on the inner surface 1111 of the cover lid 111 is fluidly connected to the reaction space 12 via the gap 162.

When performing ALD process on the powders 121 in the reaction space 12, the air intake line 173 transports the precursor gas to the reaction space 12 such that the precursor gas comes in contact with the powders 121 in the reaction space 12 and forms a thin film on the surface of each powder 121. The precursor gas transported to the reaction space 12 also passes through the gap 162, comes in contact with the monitor wafer 163 on the cover lid 111, and forms a thin film on the surface of the monitor wafer 163.

In practice, the thickness of the thin film formed on the surface of the monitor wafer 115 and the thickness of the thin film formed on the surface of the powder 121 can be measured to calculate a relation between the two thin films, such as making a comparison chart of the powder 121 and the monitor wafer 163 on their thin film thickness. And subsequently, the thickness of a thin film on the powder 121 can be inferred or obtained by measuring the thickness of the thin film on the monitor wafer.

In specific, a protrusion having an external thread is disposed at one end of the securing portion 165, and a fixing hole having an internal thread is disposed on the inner surface 1111 of the cover lid 111, wherein the securing portion 165 may be fixed to the fixing hole of the cover lid 111. In practice, different securing portions 165 can be selected based on their heights according to specific criteria or condition requirement, so as to adjust the size of the gap 162 between the inner surface 1111 of the cover lid 111 and the fan unit 161. For example, securing portions 165 with suitable height are selected based on factors like a flow of gas transported to the reaction space 12, a flow of precursor gas, or an amount of powders 121, so as to assist the precursor gas to contact the monitor wafer 163.

In one embodiment, a recess 1113 is disposed on the inner surface 1111 of the cover lid 111, and the fan unit 161 and/or the monitor wafer 163 are disposed in the recess 1113. When the cover lid 111 covers the chamber 113, the recess 1113 on the cover lid 111 and a space 1131 in the chamber 113 form the reaction space 12.

The recess 1113 in the cover lid 111 and the space 1131 in the chamber 113 can have any geometric shape, like polygonal recess, wavy circular recess, circular cylindrical recess, etc. As shown in FIG. 4, the recess 1113 on the cover lid 111 is a wavy circular recess, and the space 1131 on the chamber 113 is a wavy circular recess. When the cover lid 111 covers the chamber 113, the reaction space 12 formed between the cover lid 111 and the chamber 113 has a wavy circular columnar shape.

By designing the reaction space 12 of the vacuum chamber 11 to be wavy circular columnar or polygonal columnar, the gas transported by the air intake line 173 or the gas line 175 is enhanced to spread throughout to all places in the reaction space 12 and to blow the powders 121 around in the reaction space 12.

Moreover, when the reaction space 12 has a wavy circular columnar shape or a polygonal columnar shape, some of the powders 121 rotate with the vacuum chamber 11 until a specific angle and then gradually fall or drop down due to gravity force. As such, the powders 121 in the reaction space 12 are fully and evenly stirred.

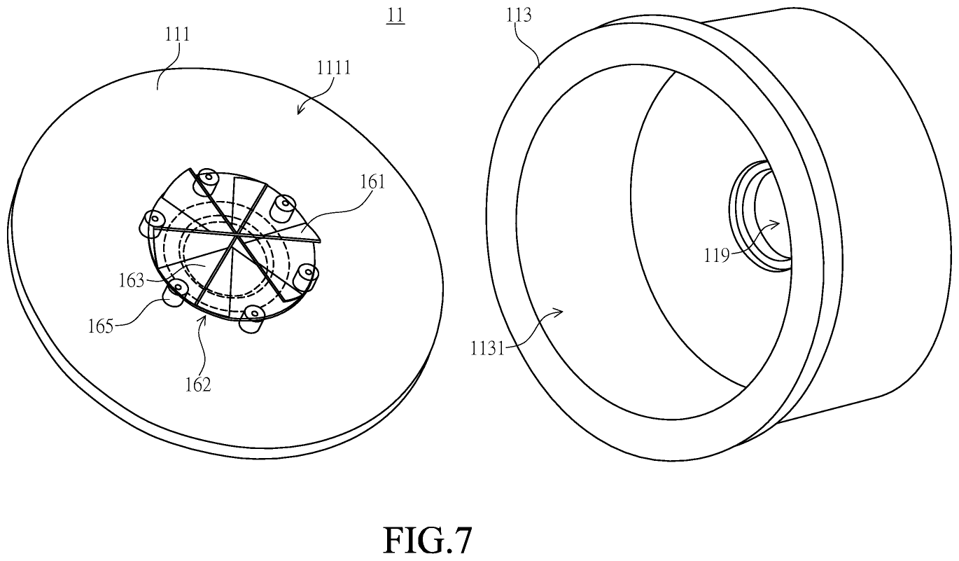

Disposing the recess 1113 on the inner surface 1111 of the cover lid 111 is merely an embodiment of the present disclosure and the present disclosure is not limited thereto. As shown in FIG. 7, there is no recess 1113 disposed on the inner surface 1111 of the cover lid 111, and the fan unit 161 and/or the monitor wafer 163 are disposed directly on the inner surface 1111 of the cover lid 111.

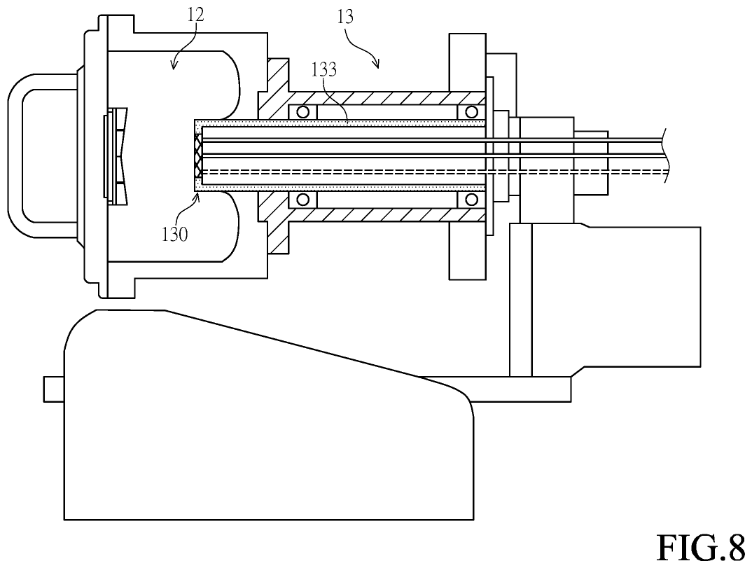

A through hole 119 is disposed on the inner bottom surface of the chamber 113, as shown in FIG. 4 and FIG. 7, and a part of the shaft sealing device 13 is disposed in the through hole 119, like putting one end of the inner tube 133 of the shaft sealing device 13 in the through hole 119 as shown in FIG. 2. In different embodiments, the part of the shaft sealing device 13 may pass through the through hole 119 and be positioned in the reaction space 12. For example, the part of the inner tube 133 of the shaft sealing device 13 may pass through the through hole 119 and extend from the accommodating space 132 of the outer tube 131 into the reaction space 12 to form a protruding tube part 130 in the reaction space 12, wherein a part of the air extraction line 171, a part of the at least one air intake line 173 and/or a part of the at least one gas line 175 are positioned in the protruding tube part 130 as shown in FIG. 8.

In one embodiment, the powder atomic layer deposition apparatus with special cover lid 10 further includes a support base 191 and at least one mount bracket 193, wherein the support base 191 is a board body for placing the driving unit 15, the vacuum chamber 11, and the shaft sealing device 13 thereon. The support base 191 is connected to the driving unit 15, and is connected to the shaft sealing device 13 and the vacuum chamber 11 via the driving unit 15. The shaft sealing device 13 and/or the vacuum chamber 11 can also be connected to the support base 191 via at least one support member so as to enhance the stability of connection.

The support base 191 is connected to the mount bracket 193 via at least one connecting shaft 195, wherein the number of mount brackets 193 is two and the two mount brackets 193 are respectively disposed at two sides of the support base 191. The support base 191 is rotatable relative to the mount brackets 193 with the connecting shaft 195 as axis, so as to change an inclination angle of the driving unit 15, the shaft sealing device 13, and the vacuum chamber 11, and in turn assist in the formation of a thin film with a uniform thickness on the surface of each powder 121.

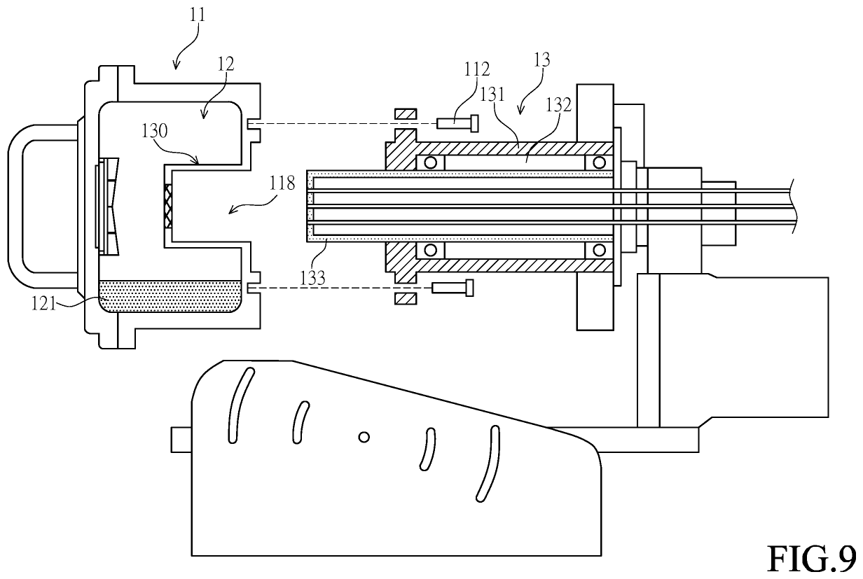

In one embodiment as shown in FIG. 9, the vacuum chamber 11 is connected to and fixed to one end of the shaft sealing device 13 via at least one fixing member 112 such as screws. The fixing member 135 being a screw is merely an example of the present disclosure, and in practice the vacuum chamber 11 may be fixed to the shaft sealing device 13 via the fixing member 112 of any formation. For example, the vacuum chamber 11 and the shaft sealing device 13 may be connected by a detachable fixing member 112 like a cylinder connector, a locking/snap mechanism, a latch, a fast-release device, screw threads, etc.

In another embodiment, the vacuum chamber 11 has a recess 118 disposed on a bottom of the vacuum chamber 11 for accommodating a part of the shaft sealing device 13, and the filter unit 139 is disposed in the recess 118, wherein the bottom of the vacuum chamber 11 faces the cover lid 111. The recess 118 extends from the bottom of the vacuum chamber 11 into the reaction space 12, and the inner tube 133 of the shaft sealing device 13 extends from the accommodating space 132 of the outer tube 131 to the outside and protrudes from the shaft sealing device 13 and the outer tube 131. When the vacuum chamber 11 and the shaft sealing device 13 are being connected, the part of the inner tube 133 protruding from the shaft sealing device 13 is inserted into the recess 118 so that the inner tube 133 and the recess 118 form a protruding tube part 130 in the reaction space 12.

The above disclosure is only the preferred embodiment of the present disclosure, and not used for limiting the scope of the present disclosure. All equivalent variations and modifications on the basis of shapes, structures, features and spirits described in claims of the present disclosure should be included in the claims of the present disclosure.

1. A powder atomic layer deposition apparatus with special cover lid, comprising:
a vacuum chamber, comprising a cover lid and a chamber, wherein an inner surface of the cover lid covers the chamber to form a reaction space between the cover lid and the chamber;
at least one fan unit, disposed on the inner surface of the cover lid;
a shaft sealing device, connected to the vacuum chamber;
a driving unit, connected to the shaft sealing device, wherein the driving unit drives the vacuum chamber to rotate through the shaft sealing device;
at least one air extraction line, fluidly connected to the reaction space of the vacuum chamber, for extracting a gas from the reaction space; and
at least one air intake line, fluidly connected to the reaction space of the vacuum chamber, for transporting a precursor gas or a gas to the reaction space, wherein the gas flows toward the fan unit on the inner surface of the cover lid and the fan unit drives the gas to blow the powders around in the reaction space.

2. The powder atomic layer deposition apparatus with special cover lid of claim 1, further comprising a monitor wafer disposed on the inner surface of the cover lid and located between the fan unit and the cover lid.

3. The powder atomic layer deposition apparatus with special cover lid of claim 2, further comprising a plurality of securing portions disposed on the inner surface of the cover lid, wherein the securing portions protrude from the inner surface of the cover lid, the fan unit is disposed on the securing portions, and there is a gap between the fan unit and the cover lid.

4. The powder atomic layer deposition apparatus with special cover lid of claim 2, wherein the cover lid comprises a recess disposed on the inner surface of the cover lid, and the monitor wafer and the fan unit are disposed in the recess.

5. The powder atomic layer deposition apparatus with special cover lid of claim 4, wherein the recess in the cover lid is a wavy circular recess, the chamber comprises a space formed by a wavy circular recess, and the reaction space formed by the cover lid and the chamber has a wavy circular columnar shape.

6. The powder atomic layer deposition apparatus with special cover lid of claim 1, wherein the air intake line comprises at least one gas line fluidly connected to the reaction space of the vacuum chamber, for transporting the gas to flow toward the fan unit on the inner surface of the cover lid, and the gas is driven by the fan unit to blow the powders around in the reaction space.

7. The powder atomic layer deposition apparatus with special cover lid of claim 6, wherein the shaft sealing device comprises an outer tube and an inner tube, the outer tube comprises an accommodating space for accommodating the inner tube, and the inner tube comprises a connection space for accommodating the air extraction line, the air intake line, and the gas line.

8. The powder atomic layer deposition apparatus with special cover lid of claim 7, further comprising:
a heater, disposed in the inner tube for heating the connection space of the inner tube; and
a temperature sensing unit, disposed in the inner tube for measuring a temperature of the connection space of the inner tube.

9. The powder atomic layer deposition apparatus with special cover lid of claim 1, wherein the vacuum chamber is fixed to the shaft sealing device via at least one fixing member and separates from the shaft sealing device when the fixing member is dislodged.

10. The powder atomic layer deposition apparatus with special cover lid of claim 1, wherein the fan unit comprises a mount rack and a plurality of blades, and the blades are disposed on the mount rack and protrude toward the chamber.

11. A powder atomic layer deposition apparatus with special cover lid, comprising:
a vacuum chamber, comprising a cover lid and a chamber, wherein an inner surface of the cover lid covers the chamber to form a reaction space between the cover lid and the chamber;
at least one fan unit, disposed on the inner surface of the cover lid;
a shaft sealing device, comprising an outer tube and an inner tube, the outer tube having an accommodating space for accommodating the inner tube and the inner tube having a connection space, wherein the inner tube extends from the accommodating space of the outer tube to the reaction space of the vacuum chamber and forms a protruding tube part in the reaction space;
a driving unit, connected to the shaft sealing device, wherein the driving unit drives the vacuum chamber to rotate through the shaft sealing device;
at least one air extraction line, fluidly connected to the reaction space of the vacuum chamber, for extracting a gas from the reaction space; and
at least one air intake line, fluidly connected to the reaction space of the vacuum chamber, for transporting a precursor gas or a gas to the reaction space, wherein the gas flows toward the fan unit on the inner surface of the cover lid and the fan unit drives the gas to blow the powders around in the reaction space.

12. The powder atomic layer deposition apparatus with special cover lid of claim 11, further comprising a monitor wafer disposed on the inner surface of the cover lid and located between the fan unit and the cover lid.

13. The powder atomic layer deposition apparatus with special cover lid of claim 12, further comprising a plurality of securing portions disposed on the inner surface of the cover lid, wherein the securing portions protrude from the inner surface of the cover lid, the fan unit is disposed on the securing portions, and there is a gap between the fan unit and the cover lid.

14. The powder atomic layer deposition apparatus with special cover lid of claim 12, wherein the cover lid comprises a recess disposed on the inner surface of the cover lid, and the monitor wafer and the fan unit are disposed in the recess.

15. The powder atomic layer deposition apparatus with special cover lid of claim 14, wherein the recess in the cover lid is a wavy circular recess, the chamber comprises a space formed by a wavy circular recess, and the reaction space formed by the cover lid and the chamber has a wavy circular columnar shape.

16. The powder atomic layer deposition apparatus with special cover lid of claim 11, wherein the air intake line comprises at least one gas line fluidly connected to the reaction space of the vacuum chamber, for transporting the gas to flow toward the fan unit on the inner surface of the cover lid, and the gas is driven by the fan unit to blow the powders around in the reaction space.

17. The powder atomic layer deposition apparatus with special cover lid of claim 16, further comprising:
a heater, disposed in the inner tube for heating the connection space of the inner tube; and
a temperature sensing unit, disposed in the inner tube for measuring a temperature of the connection space of the inner tube.

18. The powder atomic layer deposition apparatus with special cover lid of claim 11, wherein the fan unit comprises a mount rack and a plurality of blades, and the blades are disposed on the mount rack and protrude toward the chamber.

19. The powder atomic layer deposition apparatus with special cover lid of claim 11, wherein the vacuum chamber is fixed to the shaft sealing device via at least one fixing member and separates from the shaft sealing device when the fixing member is dislodged.

20. The powder atomic layer deposition apparatus with special cover lid of claim 19, wherein the inner tube of the shaft sealing device protrudes from the outer tube, the vacuum chamber comprises a recess disposed at a bottom of the vacuum chamber, and the recess extends from the bottom into the reaction space for accommodating the inner tube that protrudes from the outer tube.
